(19) United States
(12) Patent Application Publication
(10) Pub. No.: US 2026/0307983 A1
(43) Pub. Date: Oct. 8, 2026

(54) METHOD FOR PRODUCING A MICROELECTROMECHANICAL DEVICE COMPRISING A CAP STRUCTURE AND A MICROELECTROMECHANICAL DEVICE

(71) Applicant: Robert Bosch GmbH, Stuttgart (DE)

(72) Inventors: Heribert Weber, Nuertingen (DE); Franziska Rohlfing, Leonberg (DE); Peter Schmollngruber, Aidlingen (DE); Sophielouise Mach, Reutlingen (DE)

(21) Appl. No.: 19/474,810

(22) PCT Filed: Jun. 21, 2024
(86) PCT No.: PCT/EP2024/067471

§ 371 Date: Oct. 13, 2025

(30) Foreign Application Priority Data
Jul. 26, 2023 (DE) 10 2023 207 100.2

(51) Int. Cl. B81C 1/00; B81B 7/00

(52) U.S. Cl. CPC B81C 1/00595; B81B 7/0061; B81B 2201/0264; B81B 2203/0315; B81B 2203/0338; B81C 2201/0105; B81C 2201/0132; B81C 2201/014; B81C 2201/0174

(57) ABSTRACT

A method for producing a microelectromechanical device including a functional unit, a cavity, and a cap structure that covers the cavity and has a cavity access. The cap structure is produced by sequentially depositing layers of material onto a cap substrate. The functional unit is connected to the cap structure. An inlet channel in the cavity access is created in the cap structure by etching. During the production of the cap structure, an inlet channel, an outlet channel which opens into the cavity, and a lateral channel which extends parallel to a surface of the cap substrate and opens into the at least one inlet channel and into the at least one outlet channel are created in the cap structure. The cap structure, a first etch stop structure is also created in the cap structure to limit the depth of the inlet channel.

### FIELD

The present invention relates to a method for producing a microelectromechanical devices and a microelectromechanical device.

### BACKGROUND INFORMATION

Microelectromechanical devices, also referred to as MEMS devices, and methods for producing them are described in the related art.

U.S. Pat. No. 10,626,008 B2 describes a microelectromechanical device and a method for producing it. The device is made of semiconductor material and comprises a sensor region with a plurality of cavities. A cap wafer comprising a cavity access covers said sensor region.

U.S. Pat. No. 10,508,029 B2 describes a MEMS pressure sensor and a method for producing it. A cap wafer is placed on the pressure sensor by means of eutectic bonding and at least one cavity is created between the pressure sensor and the cap wafer.

U.S. Pat. No. 10,407,299 B2 relates to a MEMS sensor, for example an inertial sensor, comprising a bottom cap wafer and a top cap wafer, between which the sensor structure is configured. The MEMS sensor can comprise a plurality of cavities, wherein at least one cavity can be at ambient pressure via a vent channel. A method for producing the sensor is described as well.

### SUMMARY

According to an example embodiment of the present invention, a method for producing a microelectromechanical device comprising a functional unit, a cavity, and a cap structure that covers the cavity and has at least one cavity access is provided, in which the cap structure is produced by sequentially depositing layers of material onto a cap substrate, the functional unit is connected to the cap structure and at least one inlet channel in the at least one cavity access is created in the cap structure by means of etching, wherein, during the production of the cap structure, at least one inlet channel, at least one outlet channel which opens into the cavity, and at least one lateral channel which extends parallel to a surface of the cap substrate and opens into the at least one inlet channel and into the at least one outlet channel are created in the cap structure, and wherein, during the production of the cap structure, a first etch stop structure is created in the cap structure to limit the depth of the at least one inlet channel.

Creating a cavity access which comprises an inlet channel, an outlet channel and a lateral channel that extends parallel to a surface of the cap substrate and opens into the at least one inlet channel and into the at least one outlet channel, and providing a first etch stop structure to limit the depth of the at least one inlet channel, protects the functional unit of the microelectromechanical device against a potential undesired etching attack during the creation of the inlet channel. The first etch stop structure reliably limits the etching depth during the production of the inlet channel, and the inlet channel is created in the cap structure only as far as the intended etch stop structure, without the inlet channel passing directly into the cavity, so that the cavity access can be produced in a manner that protects the functional unit from etching attack. This also enables a high degree of freedom in the design of the cavity access. The mouth of the outlet channel into the cavity can be selected independently of the position of the inlet opening of the inlet channel on the surface of the cap structure, for instance, so that both positions and the respective geometric shape of the channels can be optimized to the individual conditions. At least in a portion of the cavity access, at least one geometric dimension can moreover be created independently of the minimum structural size that can be achieved or resolved by the photolithography process being used. The first etch stop structure created in the cap structure can also facilitate further production steps of the method for producing the device; for example making the process of creating recesses in a cavity region and/or a bond pad region or a through-opening that penetrates the cap structure in a bond pad region easy and reliable, or saving time by simultaneously structuring different regions of the device that may be subject to an ARDE effect (aspect ratio dependent etching). Creating etch stop structures thus makes it possible to increase the design freedom during the production of the cap structure. Creating at least a first etch stop structure also makes it possible to construct the cap structure using thinner and/or fewer material layers, for instance, which are then effectively protected from etching attack by the etch stop structure.

Microelectromechanical devices can in particular be semiconductor-based devices with microstructures that comprise mechanical, optical, physical and/or chemical components and/or functions, for instance, and can, for example, be used as miniaturized sensors or actuators. The microelectromechanical device can be a surroundings sensor, for example, for instance a pressure sensor. A microelectromechanical device configured as a pressure sensor can be based on a variety of pressure measurement principles, for example as a piezoresistive or piezoelectric pressure sensor or also as a capacitive pressure sensor. However, the devices and methods described in this application can generally also be applied to other MEMS devices, for example those configured as actuator devices.

According to an example embodiment of the present invention, the functional unit of the microelectromechanical device can be a functional part of the device and can, for example, be embodied as a sensor unit with a sensing region. In the sensing region, the functional unit can comprise one or more movable microstructures, for example, which are designed to carry out the sensor function of the functional unit. The movable microstructure can be configured as a membrane, for instance. The functional unit can also be or comprise an electronic circuit or be connected to a circuit unit. The circuit and/or the circuit unit can be configured as an ASIC, for example.

According to an example embodiment of the present invention, the cavity of the microelectromechanical device can be a hollow space formed between the cap structure and the functional unit which enables the mobility of a microstructure of the sensing region within the cavity, for example, and enables interaction of the microstructure with the surroundings of the microelectromechanical device via the cavity access; for instance in order to be able to acquire the ambient pressure. To enable measurements using reference-based measurement principles, the microelectromechanical device can optionally comprise further cavities; for example, also hermetically sealed cavities with a predefined reference pressure.

The cap structure of the microelectromechanical device can form a microstructurally produced protective covering for the functional unit, which protects a sensing region of the functional unit from mechanical effects or undesirable environmental influences, for example, and also enables controlled and limited interaction of the sensing region with the surroundings via a defined cavity access. The cap structure is created layer by layer by depositing layers of material onto a flat cap substrate, wherein the material layers can substantially form layer planes with a larger areal extent parallel to the cap substrate surface than across the height of the layers. The material layers can be structured in individual production steps to create specific functional cap regions or to prepare further production steps.

According to an example embodiment of the present invention, the inlet and outlet channels created in the cap structure can be configured orthogonally to the layer planes, for example, while the at least one lateral channel can be configured such that it extends parallel to the layer planes and/or parallel to the cap substrate surface. Channels that extend parallel to the layer planes, for instance the at least one lateral channel that connects the at least one inlet channel and the at least one outlet channel, can be configured as buried hollow space structures. The term buried hollow space structures refers to enclosed free spaces in layer structures that are created using special production techniques. The lateral channel can form a lateral branch on the perimeter of the inlet channel and/or the outlet channel. In a plane parallel to the surface of the cap substrate, the lateral branch can open into a side wall of the inlet channel and/or the outlet channel at a right angle or at an acute or obtuse angle. The lateral channel can connect the inlet channel and the outlet channel to one another, for example to enable a fluid connection between an inlet of the inlet channel at the surface of the cap structure and an outlet of the outlet channel into the cavity. The inlet can be laterally offset from the outlet, in which case the offset can correspond to the length of the lateral channel. A lateral offset can be an offset along a layer plane perpendicular to the center axis of the inlet channel and/or the outlet channel, for instance. In principle, however, according to other embodiments, it is also possible that a plurality of lateral channels are connected to one another such that the outlet channel is aligned with the inlet channel and there is no lateral offset between the inlet and the outlet. The inlet channel does not open directly into the cavity, but is instead connected to the cavity only indirectly via at least one lateral channel and at least one outlet channel. The inlet channel can be configured as a blind hole. The lateral channel can open into the inlet channel at a channel base at the end of the inlet channel, for example, or at any position between the channel base and an inlet of the inlet channel on the surface of the cap structure. The outlet channel can be configured as a blind hole. The lateral channel can open into the outlet channel at a channel base at the end of the outlet channel, for instance, or at any position between the channel base and an outlet of the outlet channel at the cavity. Due to the course of the inlet channel, the lateral channel and the outlet channel, the cavity access at least comprises deflections at the transitions of the respective channel portions at which a change in direction of a fluid flow through the cavity access occurs. In a plane perpendicular to the surface of the cap substrate, the cavity access can correspond geometrically to or approximate a Z-shape or a point-mirrored L-shape, for example, and, in a plane parallel to the surface of the cap substrate, it can have any geometric shape. The geometric dimensions and/or shapes of the inlet channel, the lateral channel and/or the outlet channel can be selected such that only gaseous media can flow through the cavity access, whereas liquids or solid particles above a specific particle size are prevented from entering the cavity. This can be further facilitated by the multiple deflections in the cavity access. In principle, the at least one lateral channel can have a smaller channel cross-section than the inlet channel and/or the outlet channel at least in some regions. Alternatively, it is possible that the lateral channel has a larger channel cross-section than the inlet channel and/or the outlet channel at least in some regions. Depending on the embodiment, the inlet channel can have a larger or a smaller channel cross-section than the outlet channel. In a plane parallel to the surface of the cap substrate, the at least one lateral channel can have any shape and/or any geometric dimensions. The channel cross-sections of the cavity access, the number of inlet channels, the number of outlet channels, the number of lateral channels, the number of connections between lateral channels and the number of lateral channels that open into an inlet channel and/or outlet channel can be adapted to the intended type of microelectromechanical device, to the operating principle of the functional unit and to the respective associated requirements. With small channel cross-sections and/or slot-shaped channel cross-sections, for example, they can provide a high level of protection of the cavity from particles and liquids, or with large channel cross-sections and/or a plurality of lateral channels and/or inlet channels and/or outlet channels, they can prioritize low flow resistance.

According to an example embodiment of the present invention, to optimize the surface region of a MEMS device, e. g., a sensor and/or actuator device, the inlet channel can be disposed in the cap structure above a sensing region of the functional unit. The inlet channel can be created in the surface of the cap structure substantially centrally, for example, or at least in a region close to the center. This can, for example, enable a later molding process, such as film assisted molding (FAM) of the microelectromechanical device, in which the device is provided with a housing consisting of a robust encapsulating material outside the at least one inlet channel for improved protection. In terms of process technology, this requires external sealing of the inlet channel and then a sufficient cover surface surrounding the inlet channel for attaching a protective film, so that disposing the inlet channel close to the center is advantageous.

According to an example embodiment of the present invention, the device can in principle also comprise a plurality of cavity accesses. A cavity access can generally comprise an inlet channel, a lateral channel, and an outlet channel, for instance. It is also possible that the cavity access comprises a plurality of inlet channels that open into a lateral channel. It is also possible that the cavity access comprises a plurality of outlet channels that open into a lateral channel. It is also possible that the cavity access comprises a plurality of lateral channels that open into an inlet channel. It is also possible that the cavity access comprises a plurality of lateral channels that open into an outlet channel. It is also possible that the cavity access comprises a plurality of lateral channels that open into an inlet channel and/or outlet channel. It is also possible that a plurality of lateral channels are interconnected, wherein at least one lateral channel of the plurality of lateral channels can open into an inlet channel and at least one lateral channel of the plurality of lateral channels can open into an outlet channel. It is thus also possible that a plurality of cavity accesses, a plurality of inlet channels and/or a plurality of outlet channels are provided, which can optionally open into a lateral channel. Any combinations of the above-described variants are possible too.

The terms “inlet” and “outlet” and “inlet channel” and “outlet channel” are used solely to facilitate understanding of the device and the method. It is of course also possible that, depending on the design and application of the microelectromechanical device, the cavity access can alternatively or additionally form a vent, so that fluid can also enter the outlet channel from the cavity and exit the inlet channel at the surface of the cap structure. The cavity access can therefore also allow bidirectional fluid movement between the surroundings and the cavity.

The material layers, which can in particular be semiconductor-based material layers such as monocrystalline or polycrystalline silicon layers or layers of silicon compounds such as silicon dioxide (SiO₂) or silicon nitride (Si₃N₄), can be deposited using conventional deposition processes from semiconductor technology. The material layers are deposited on a substrate, also referred to as a wafer, for example a silicon substrate. A material layer can be deposited on the substrate or an already deposited material layer continuously, or it can be deposited only in some sections, for example by masking at defined positions or sections. Structuring or creating hollow spaces or recesses can be done using etching processes, for example. Created hollow spaces can be closed again, for example with another material layer, so that a buried hollow space structure results. The etching processes can be advantageous be carried out using dry etching processes, such as plasma etching. In principle, however, wet chemical etching processes can be used as well. The device can also be processed in further optional production steps using other processing methods; for example thinned by means of a grinding process and/or chemically mechanically polished (CMP process).

The functional unit can be connected to the cap structure, for example in a bonding region, by means of a bonding structure and using a conventional wafer bonding process from semiconductor technology. The bonding structure can connect the cap structure to the functional unit in a mechanical and/or at least partially electrically conductive and/or at least partially electrically non-conductive manner. The bonding structure can be configured as a bonding frame. The bonding structure can, for instance, be made from a thermocompressive material, for example containing gold, or from a eutectic material, for example containing aluminum, silicon, germanium, copper and/or gold, or from a material containing tin and/or copper, or from a polymer-based material or a glass frit material. At least one dielectric layer, for example containing silicon (Si), aluminum (Al), titanium (Ti), tantalum (Ta), oxygen (O) and/or nitrogen (N), and/or at least one adhesion-enhancing layer, for example containing tantalum (Ta), titanium (Ti), tungsten (W), nickel (Ni), nitrogen (N) and/or platinum (Pt), or a layer combination of layers comprising the aforementioned materials, which can optionally also be used to produce electrical conductor tracks, is provided between the bonding structure and the cap structure. The aforementioned chemical elements can also be present in the layers as chemical compounds, for example as silicon dioxide (SiO₂), silicon nitride (Si₃N₄), silicon oxynitride (SiON), titanium oxide (TiO₂), tantalum oxide (Ta₂O₅), and/or aluminum oxide (Al₂O₃) in a dielectric layer or, in an adhesion-enhancing layer, for example as tantalum nitride (TaN), titanium nitride (TiN), and/or titanium tungsten (TiW).

According to an example embodiment of the present invention, the functional unit can be provided on a separate functional wafer, for example, and connected to the cap structure provided on another wafer, here on the cap substrate, using a wafer bonding process. The microelectromechanical device can thus, for instance, comprise a cap wafer and a functional wafer connected to it. In the lateral direction, i.e. viewed parallel to the substrate surfaces, for example, the microelectromechanical device can comprise a bonding region provided for mechanically and/or electrically connecting the functional unit to the cap structure, an adjoining sensing region of the functional unit, in which the device is configured to carry out a sensor function by means of at least one microstructure, and a bond pad region that can be electrically connected, for example to an evaluation circuit, by means of wire bond connections.

According to an example embodiment of the present invention, the etch stop structure can be a material layer or a laterally delimited layer portion of a material layer that preferably exhibits a higher etch selectivity or etch resistance than adjacent material layers and can prevent an etching process or etching progress into material layers protected by the etch stop structure. The material layer can be more chemically and/or physically resistant than adjacent layers, for instance, and/or have a significantly lower etching rate than adjacent layers. The etch stop structure is advantageously tailored to the etching processes and etching media used to produce the cap structure. Alternatively, it is also possible, for example, to select a material layer for the etch stop structure that is resistant to a wet chemical and/or gaseous etching process, for instance a plasma etching process or gas phase etching process. The first etch stop structure can be created in the cap structure such that it is disposed opposite to a provided inlet opening of the inlet channel and, after production of the inlet channel, limits the length or depth of said channel, for example by forming a channel base at the end of the inlet channel. The etch stop structure can be effective on both sides, so that it is not only advantageously useful for the creation of the inlet channel, but for example also for the reliable and easy creation of recesses in the cap structure. The first etch stop structure can, for example, be used to easily and reliably create recesses of varying depths in the bond pad region and the sensing region.

According to one example embodiment of the present invention, a second etch stop structure can be created in the cap structure in the region of the at least one outlet channel during the production of the cap structure. The second etch stop structure can facilitate the production steps of the cap structure that precede the creation of the outlet channel and enables improved control and regulation of the depth of the outlet channel. The second etch stop structure can form a preliminary etch stop structure that facilitates the structuring of material layers prior to the creation of the outlet channel. In this embodiment, the outlet channel can be created by etching into the cap structure and through the etch stop layer. The second etch stop structure can optionally limit a preliminary etching depth during the creation of the outlet channel. In principle, it is possible to create further etch stop structures in the cap structure during the production of the cap structure, for instance to further facilitate the creation of further recesses, for example cavity recesses or bond pad region recesses which will be discussed in the following, and to ensure process reliability.

According to one example embodiment of the present invention, the first etch stop structure and the second etch stop structure can be created as a continuous etch stop layer. The first etch stop structure and the second etch stop structure can thus form a common etch stop layer and merge directly into one another. The continuous etch stop layer enables an etch stop for both the at least one inlet channel, the at least one outlet channel and also for other regions of the cap structure, so that further processing of the cap structure is facilitated and process reliability can be ensured. This also makes it possible to achieve a very flat cap structure with few material layers, for example only a silicon dioxide layer and a silicon layer.

According to one example embodiment of the present invention, the first and/or the second etch stop structure can be created with a silicon dioxide layer. This creates a particularly easy to produce and at the same time very effective etch stop structure. The silicon dioxide layer can, for instance, exhibit high chemical etch resistance in a plasma etching process, so that the creation of the inlet channel and/or optionally also the outlet channel can be controlled and the depth can be reliably controlled or limited by the etch stop structure. In a subsequent process step, the etch stop structure can optionally be at least partially removed.

According to one example embodiment of the present invention, at least one channel support structure and/or at least one channel block structure can be created in the at least one lateral channel. A channel support structure can be a structure, for example a column-shaped structure, which extends in the channel space over the full height of the lateral channel and contributes to improved stability of the cap structure. A channel block structure can be a, for example pedestal-shaped, structure, which extends in the channel space of the lateral channel and causes narrowing of the lateral channel in some sections. A channel block structure can be used to block the cavity access, for example for liquids or solid particles above a certain particle size, and thus prevent contamination of the cavity and the sensitive microstructures of the functional unit. The channel block structure can form a filter region of the cavity access. The multiple deflections of the cavity access over the angled course of the channel further promotes the retention of liquids and particles.

According to one example embodiment of the present invention, the lateral channel can be created in the cap substrate of the cap structure. This enables easy creation of the lateral channel by machining the cap substrate prior to the deposition of material layers onto the cap substrate. It also makes it possible to achieve a flat overall construction of the cap structure.

According to one example embodiment of the present invention, the at least one lateral channel can be created by depositing, structuring and at least partially removing at least one sacrificial material layer. The sacrificial material layer can be a silicon dioxide layer, for example. After deposition of the sacrificial material layer, which can optionally also be deposited in multiple layers and/or can consist of multiple layers, a material layer, for example a silicon layer, can be deposited on the sacrificial material layer and at least one etching access can be created in the material layer made of silicon in order to enable later removal of the sacrificial material layer. The at least one etching access can, for instance, be created by microperforating the material layer made of silicon in order to then be able to easily close the etching accesses again after removing the sacrificial material layer.

In principle, it is not impossible to provide a plurality of lateral channels at different layer heights and/or at least one lateral channel in the cap substrate and/or a lateral channel in the material layer structure. A plurality of lateral channels allow the flow resistance in the cavity access to advantageously be reduced. At least one additional lateral channel can moreover serve as a bypass channel if another lateral channel is blocked, for example by particle accumulation, or has reduced passability.

According to another embodiment of the present invention, after structuring a first sacrificial material layer, in particular immediately after structuring a first sacrificial material layer, at least in a region in which the first sacrificial material layer has been removed, a second sacrificial material layer, a first silicon layer, an etch stop layer and a second silicon layer are deposited one after the after such that the etch stop layer is substantially completely surrounded by the first silicon layer and/or the second silicon layer. The etch stop layer can be made of silicon dioxide, for example. The described embodiment allows the creation of the lateral channel to be sensibly and efficiently linked to the creation of an etch stop structure in the lateral channel. The first sacrificial material layer, which can be made of silicon dioxide, for example, can be structured after deposition such that a sacrificial material-free region is created in the region of an inlet channel, The sacrificial material-free region is preferably configured centrally with respect to the inlet channel and its outer perimeter can extend peripherally at a defined distance from the outer perimeter of the inlet channel. After structuring the first sacrificial material layer, the second sacrificial material layer, which can be made of silicon dioxide, is deposited. The thickness of the second sacrificial material layer can later be used to set a reduced height of the at least one lateral channel in a region in which the first sacrificial material layer was removed. After depositing the second sacrificial material layer, the first and the second sacrificial material layer can optionally be structured such that sacrificial material-free regions are created that can be used to produce later channel support structures. In a subsequent step, a first silicon layer is deposited and the sacrificial material-free regions are at least partially filled. This is followed by the deposition of a silicon dioxide layer. The created surface can be planarized, for example using a CMP step, such that the silicon dioxide layer is removed from the surface of the first silicon layer outside a sacrificial material-free region in the first sacrificial material layer and remains on the first silicon layer only within a sacrificial material-free region in the first sacrificial material layer, which results in a flat surface. The silicon dioxide layer remaining on the first silicon layer in a sacrificial material-free region of the first sacrificial material layer can later be used as a first etch stop structure and/or as a second etch stop structure. In a further method step, a second silicon layer can be deposited and together with the first silicon layer structured such that at least one etching access to the first sacrificial material layer and the second sacrificial material layer is created. Depositing a second silicon layer causes the material of the silicon dioxide layer remaining on the first silicon layer in a sacrificial material-free region of the first sacrificial material layer to be completely enclosed with silicon and thus protected from etching attack when the first sacrificial material layer and the second sacrificial material layer are removed. In a further step, the at least one etching access through the first silicon layer and the second silicon layer can be closed after removal of the first sacrificial material layer and the second sacrificial material layer by depositing a third silicon layer, which makes it possible to create at least one lateral channel followed by the creation of a bonding structure. Structuring the first silicon layer, the second silicon layer and the third silicon layer together then enables the creation of at least one outlet channel that opens into at least one lateral channel. Structuring of the first and the second silicon layer and deposition of a third silicon layer can alternatively be omitted and the first and the second sacrificial material layer can be removed after the creation of the at least one outlet channel. It is optionally also possible to create a bond pad region recess in the region of bond pad structures.

In principle, it is possible that the sacrificial material layers mentioned in connection with the above-described embodiments can also be provided outside lateral channels and retained there, for example under bonding structures.

According to an advantageous embodiment of the present invention, a cavity recess and/or a bond pad region recess and/or a through-opening in the region of bond pad structures can be created in the cap structure during the production of the cap structure. The cavity recess and/or the bond pad region recess can be created, in particular etched, into already deposited material layers of the cap structure. A cavity recess can enable an enlargement of the cavity hollow space formed between the cap structure and the functional unit, i.e. achieve an enlargement of the enclosed cavity volume. This can increase the freedom of movement of a movable microstructure of the functional unit, for example, and thus, for instance, allow a greater deflection of a microstructure. A larger cavity, for example for a microelectromechanical device configured as a sensor device, can also reduce the time-dependent effect of gas leaks and/or outgassing from the layer system, such as an increase in the internal pressure of the cavity per unit time, and thus increase the service life of the sensor device. Providing a recess in the region of bond pad structures can advantageously be used to avoid having to remove the entire thickness of the cap structure, for example after the creation of the inlet channel, in order to be able to provide free access to bond pad structures. An opening that completely penetrates the cap structure can be provided in the region of bond pad structures.

According to one example embodiment of the present invention, a plurality of lateral channels which extend parallel to a surface of the cap substrate can be created in the cap structure during the production of the cap structure. At least one lateral channel can open into the inlet channel and into the outlet channel. Alternatively, a plurality of lateral channels can open into an inlet channel and/or into an outlet channel. A plurality of lateral channels can advantageously reduce the flow resistance in the cavity access, which can be favorable for sensor devices for acquiring dynamic variables, for example, while advantageously also achieving or maintaining a filter function, e.g. against particles. One lateral channel can serve as a bypass channel if another lateral channel is blocked, for example by particle accumulation, or has reduced passability. As discussed above, the lateral channels can be provided at different layer heights, for example, and/or in the cap substrate and/or in a material layer. In terms of production, however, it can be advantageous to create a plurality of lateral channels in one cap substrate plane or in one layer plane, so that the lateral channels can be provided at the same height within the layer structure. The lateral channels can be disposed opposite to one another or adjacent to one another, for example, and interconnected via the inlet channel, the outlet channel, additional channels and/or the selected channel path. The lateral channels can converge and open into one another at an angle, which can be a perpendicular angle, for example, or also an acute or obtuse angle, or be interconnected and/or enter a wall of the inlet channel and/or the outlet channel at an angle, which can be a perpendicular angle, for example, or also an acute or obtuse angle. A plurality of lateral channels can converge and open into one another in a cross-shaped or star-shaped manner, for instance, and/or can open into the inlet channel and/or the outlet channel in a cross-shaped or star-shaped manner. In principle, there is a high degree of design freedom in the arrangement of a plurality of lateral channels in relation to one another and their connection to one another. At least one inlet and/or outlet channel can come off each one of the lateral channels in a stub-like manner, for example, and create a pressure access to the cavity. However, it is also possible to allow a plurality of lateral channels to open into a common inlet channel and/or outlet channel and/or a plurality of inlet channels and/or outlet channels in a lateral channel. The lateral channels can also be interconnected outside or away from an inlet channel and/or an outlet channel. The position of the outlet into the cavity of the at least one outlet channel can be freely selectable; the outlet channel can open into the cavity offset from a movable microstructure or a sensing region of the functional unit for example. The outlet channel can open into the cavity at a created cavity recess of the cap structure, for instance, or away from such a cavity recess.

According to one example embodiment of the present invention, at least two lateral channels can be connected to one another via at least one connecting channel and/or open into one another. This can advantageously further reduce the flow resistance in the cavity access.

According to one example embodiment of the present invention, at least one first etch stop structure and/or at least one first channel block structure can be created at a distance from the cap substrate and at least one second etch stop structure and/or at least one second channel block structure can be created directly on the cap substrate. The different positions of the etch stop structures enable said structures to advantageously influence the control of etching processes in various production steps. The different positions of channel block structures and a related labyrinth effect allow the cavity access to be protected even more reliably against particle or liquid ingress.

After the inlet channel has been created in the cap structure, the inlet channel can optionally be closed again, for example by melting layer and/or substrate material with the aid of a laser and/or by depositing at least one electrically conductive and/or electrically non-conductive sealing layer. This may, for instance, be desirable for sensors in microelectromechanical devices that operate with a closed cavity and a defined enclosed cavity internal pressure, such as inertial sensors.

In principle, it is possible that the deposited silicon layers and/or the cap substrate can be doped to increase their electrical conductivity; for example so that they can then also Serve as EMC shielding. £ According to certain features of the present invention, a microelectromechanical device comprising a functional unit, a cavity, and a cap structure that covers the cavity and has at least one cavity access is also proposed, wherein the cavity access comprises at least one inlet channel, at least one outlet channel which opens into the cavity, and at least one lateral channel which extends parallel to a surface of the cap substrate and opens into the at least one inlet channel and into the at least one outlet channel, wherein the at least one inlet channel in the cap structure is limited in terms of its depth by a first etch stop structure. This makes it possible to provide a device that is simple and reliable to produce, the functional unit of which is advantageously protected from process influences during production, for example, but also from undesirable or excessive environmental influences during operation, by a cavity access comprising multiple deflections.

The device of the present invention can also include other features presented in connection with the above-described method; for example a second etch stop structure in the region of the at least one outlet channel, a first and/or second etch stop structure consisting of a silicon dioxide layer, at least one lateral channel which is created in the cap substrate and/or in the material layers of the cap structure and extends parallel to a surface of the cap substrate, at least one channel support structure and/or at least one channel block structure in the at least one lateral channel, a plurality of lateral channels, that open into the inlet channel and/or outlet channel, lateral channels that are additionally connected to one another outside an inlet channel and/or an outlet channel by at least one channel, a plurality of inlet channels and/or outlet channels that open into a lateral channel, a cavity recess and/or a recess in the bond pad region and/or a through-opening in the region of bond pad structures in the cap structure.

The above-described device and the above-escribed method can be used in MEMS sensor technology, for example. The method for producing can be used to produce any microelectromechanical devices in which a cavity comprising a cavity access is provided or required. The presented method makes it possible to prevent an etching attack on a sensing region of the device, but in principle also on other device components, such as circuit elements.

In the context of the present application, unless explicitly defined otherwise, the words “a/an” are generally not to be understood as a number word, but as indefinite articles meaning “at least one”.

The present invention permits a variety of embodiments and is explained in more detail in the following with reference to embodiment examples and the figures.

### BRIEF DESCRIPTION OF THE DRAWINGS

FIG. 1A shows a schematic sectional view of a microelectromechanical device according to a first example embodiment of the present invention.

FIG. 1B shows a schematic plan view onto a section of the device which is indicated in FIG. 1A with a dash-dotted line.

FIGS. 2A-2G show schematic sectional views showing method steps for producing the microelectromechanical device according to a first example embodiment of the present invention.

FIGS. 3A-3B show schematic sectional views showing method steps for producing the microelectromechanical device according to a second example embodiment of the present invention.

FIGS. 4A-4D show schematic sectional views showing method steps for producing the microelectromechanical device according to a third example embodiment of the present invention.

FIG. 5 shows a schematic sectional view of a microelectromechanical device according to a fourth example embodiment of the present invention.

FIG. 6 shows a schematic sectional view showing a method step for producing the microelectromechanical device according to a fifth example embodiment of the present invention.

### DETAILED DESCRIPTION OF EXAMPLE EMBODIMENTS

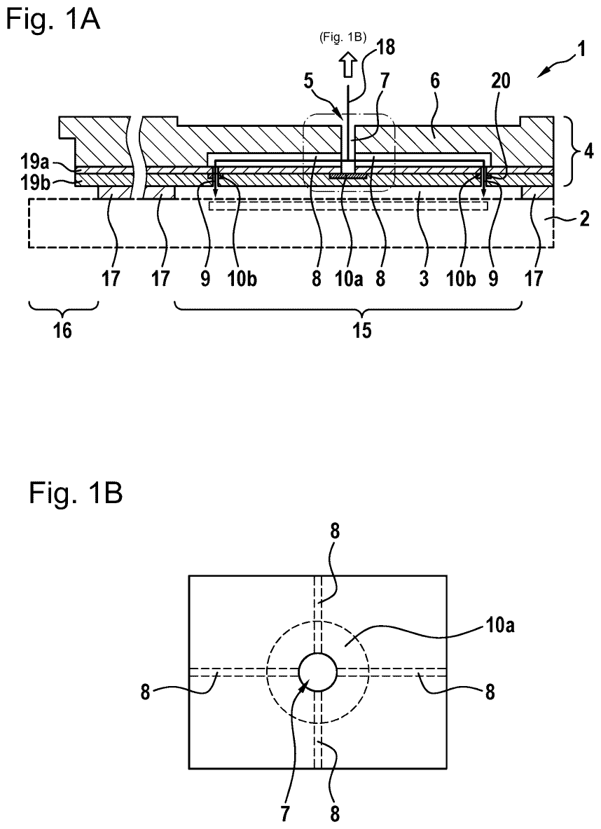

FIGS. 1A and 1B show a schematic sectional view of a microelectromechanical device 1 according to a first embodiment. The device 1 is configured as a sensor device, for example, and comprises a sensing region 15 for carrying out a sensor function and a bond pad region 16 for providing an external electrical connection; for instance to an ASIC evaluation circuit. The device 1 has a functional unit 2, which, for instance, comprises a movable microstructure as a measuring means for measuring ambient conditions, for example ambient pressure. The functional unit 2 can alternatively or additionally comprise an ASIC for signal processing. The functional unit 2 is connected in a mechanical and/or at least partially electrically conductive and/or at least partially electrically non-conductive manner to a cap structure 4 of the device 1 via bonding structures 17. The cap structure 4 protects the functional unit 2 at least partially from mechanical effects as well as from specific or excessive environmental influences. A cavity 3, which is surrounded at least partially by at least one bonding structure 17, is configured between the cap structure 4 and the functional unit 2. The cavity 3 forms a measurement space for acquiring the ambient conditions by means of the functional unit 2. The cap structure 4 comprises a cavity access 5 through which the cavity 3 can interact with the surroundings via a ventilation path 18 and through which fluid or gas flows, for example, can flow into the cavity 3 or back into the surroundings. As shown, the cavity access 5 is not configured as a through-opening, but rather as a multi-angled channel system. The cavity access 5 comprises at least one inlet channel 7, at least one outlet channel 9 that is connected to the cavity 3, and at least one lateral channel 8 which extends parallel to a surface of the cap substrate 6 and opens into the at least one inlet channel 7 and the at least one outlet channel 9. The cap structure 4 is formed by material layers that have been successively deposited on a cap substrate 6 and optionally structured and, as an example, are shown in FIGS. 1A and 1B as a first silicon layer 19a, a silicon dioxide layer 20 and a second silicon layer 19b. The lateral channels 8 are formed in the cap substrate 6. As can be seen in FIGS. 1A and 1B, the layer structure of the cap structure 4 includes a first etch stop structure 10a in the region of the at least one inlet channel 7 and optionally a second etch stop structure 10b in the region of the at least one outlet channel 9. The first etch stop structure 10a can limit the depth of the at least one inlet channel 7 during the etching of the at least one inlet channel 7. The optional second etch stop structure 10b can form a preliminary etch stop structure that facilitates the structuring of material layers prior to the creation of the outlet channel 9. The first etch stop structure 10a and optionally the second etch stop structure 10b can enable simple and reliable production of the device 1 can be made possible.

FIG. 1B shows a schematic plan view onto the section of the device 1 in the region of an inlet channel 7 which is indicated in FIG. 1A with a dash-dotted line. FIG. 1B shows that it is advantageously also possible to create a plurality of lateral channels 8 in the device 1, which can extend toward the inlet channel 7 in a cross-shaped manner and open into it as shown in the embodiment example. The creation of a plurality of lateral channels 8 can reduce the flow resistance of the cavity access 5 and/or the effects of a lateral channel 8 closed off by foreign matter on the function of the component. FIG. 1B also indicates that the first etch stop structure 10a, which, as shown in FIG. 1A, limits the channel depth of the inlet channel 7 during the etching the inlet channel 7, is positioned in the region of the inlet channel 7.

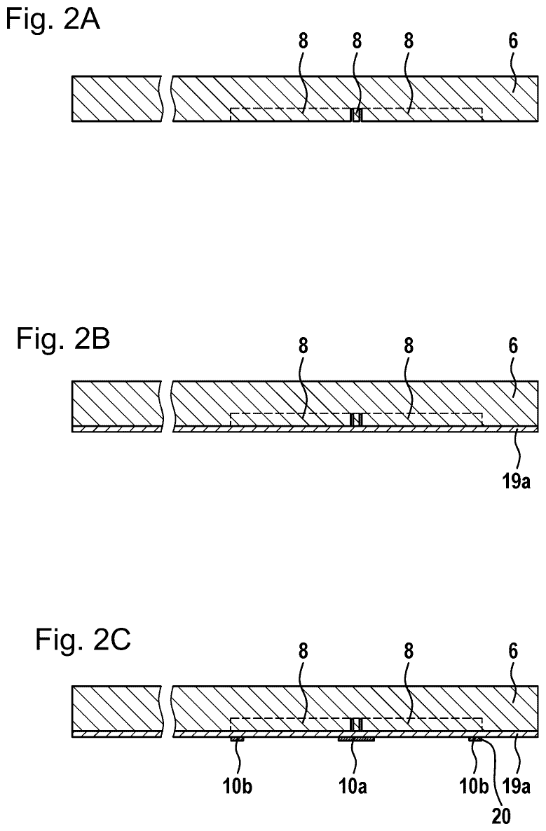

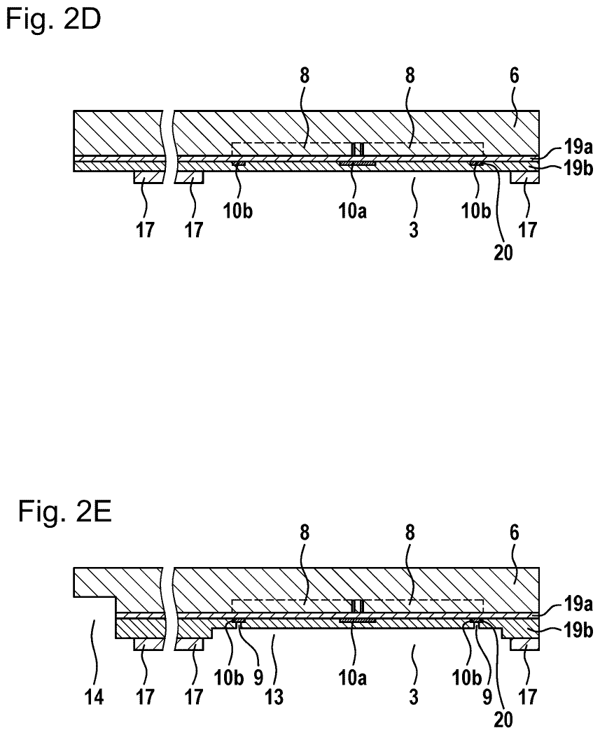

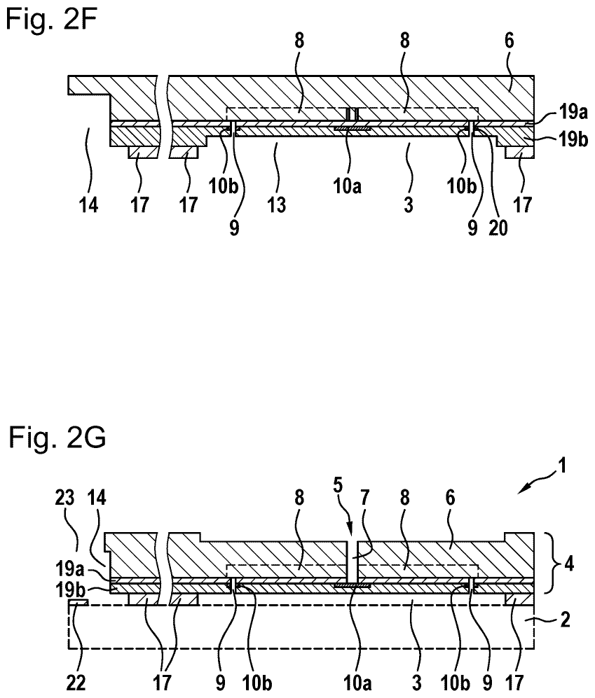

A method for producing the device 1 is described in the following with reference to FIGS. 2A to 2G. FIGS. 2A to 2F show the production of the cap structure 4, whereas FIG. 2G shows the subsequent connection of the functional unit 2 and the subsequent creation of the inlet channel 7.

In FIG. 2A, in a first production step, lateral channels 8 are created in a cap substrate 6, for instance a silicon substrate, for example by means of etching.

In FIG. 2B, in a second production step, the created lateral channels 8 are closed off with a first silicon layer 19a, so that the lateral channels 8 form a buried channel structure.

In FIG. 2C, in a third production step, a silicon dioxide layer 20 is deposited on the first silicon layer 19a and structured such that individual sections of the silicon dioxide layer 20 that form a first etch stop structure 10a and optionally a second etch stop structure 10b remain in a region of the later at least one inlet channel 7 and optionally in a region of the later at least one outlet channel 9.

In FIG. 2D, in a fourth production step, a second silicon layer 19b is deposited and optionally structured. In a fifth production step also shown in FIG. 2D, bonding structures 17, which enable a later mechanical and/or at least partially electrically conductive and/or at least partially electrically non-conductive connection of the cap structure 4 to the functional unit 2, are deposited on the second silicon layer 19b. The second silicon layer 19b can optionally be planarized using a CMP process.

FIG. 2E shows a sixth production step, in which at least a first outlet portion of the at least one outlet channel 9 and optionally a cavity recess 13 and a bond pad region recess 14 are created. The at least one second etch stop structure 10b allows the outlet portion of the at least one outlet channel 9, the cavity recess 13 and the bond pad region recess 14 to be created in a process-reliable manner and with a high degree of design freedom without the occurrence of an uncontrolled etching attack on the silicon layers 19a, 19b or the cap substrate 6.

In FIG. 2F, in a seventh production step, the outlet portion of the at least one outlet channel 9 is further deepened by at least partially removing the silicon dioxide layer 20 and the first silicon layer 19a until it opens into a lateral channel 8 and the at least one outlet channel 9 is completely formed.

FIG. 2G shows that, in accordance with an eighth production step, the functional unit 2 can be connected to the cap structure 4 via the bonding structures 17, for instance by using a wafer bonding process. After the functional unit 2 is connected to the cap structure 4, the functional wafer of the functional unit 2 and/or the cap substrate 6 of the cap structure 4 can optionally be thinned by means of a grinding and/or polishing process. Additional recesses can then optionally be created in the functional and/or cap wafer. In the region of bond pad structures 22, bond pad structures 22, which can be electrically contacted via wire bond connections and enable electrical connection to an external ASIC evaluation circuit, can be made accessible, for example by removing cap material and by creating at least one through-opening 23. In a ninth production step, the at least one inlet channel 7 is created in the cap structure 4, and the depth is advantageously limited by the first etch stop structure 10a. The creation of the at least one inlet channel 7 advantageously takes place after the above-described steps to protect the cavity 3 and the functional unit 2 from undesirable process influences through the inlet channel 7 during the production of the device 1.

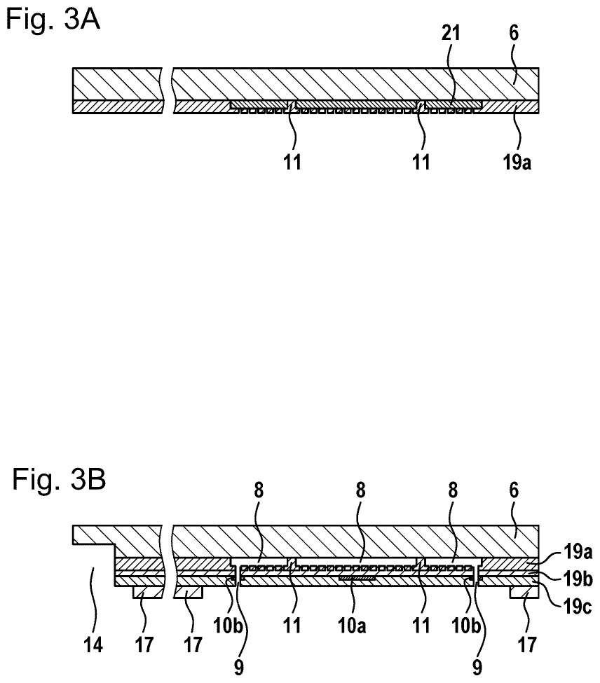

FIGS. 3A and 3B show a method for producing the microelectromechanical device 1 according to a second embodiment. According to the second embodiment, the lateral channels 8 are not created in the cap substrate 6 of the cap structure 4, but are created by depositing and later locally removing a sacrificial material layer 21 in the layer structure of the cap structure 4. The sacrificial material layer 21 can made of silicon dioxide, for example. The height of the sacrificial material layer 21 can be selected accordingly depending on the desired channel width and the desired channel cross-sectional area.

According to FIG. 3A, in a first production step, the sacrificial material layer 21 was deposited on the cap substrate 6 and structured for the subsequent production steps. In a second production step, a first silicon layer 19a is deposited and structured, wherein a portion of the sacrificial material layer 21 is exposed during structuring and an etching access to the sacrificial material layer 21 is created, for example. The first silicon layer 19a can furthermore optionally be planarized prior to structuring using a CMP step. The first silicon layer 19a can also be used to create channel support structures 11. FIG. 3A, for example, shows a microperforation of the first silicon layer 19a adjacent to the sacrificial material layer 21, which enables removal of the sacrificial material layer 21 in a third production step. After the removal of the sacrificial material layer 21, the etching accesses in the first silicon layer 19a are closed again in a fourth production step.

FIG. 3B shows further processing analogous to the second to eighth production steps of the method described in connection with FIGS. 2B to 2F. A second silicon layer 19b, a silicon dioxide layer 20 for creating the etch stop structures 10a, 10b, a third silicon layer 19c and the bonding structures 17 are successively deposited on the first silicon layer 19a, for example, and the at least one outlet channel 9 that opens up into at least one lateral channel 8 was created. Creating the etch stop structures 10a, 10c and/or the bonding structures 17 includes depositing and structuring a layer and/or a layer system. The second silicon layer 19b and/or the third silicon layer 19c can optionally also be additionally planarized and/or structured after the respective deposition. In an alternative embodiment, the structuring of the first silicon layer 19a and the deposition of the second silicon layer 19b can be omitted and the sacrificial material layer 21 can be removed in the at least one lateral channel 8 after the creation of the at least one outlet channel 9.

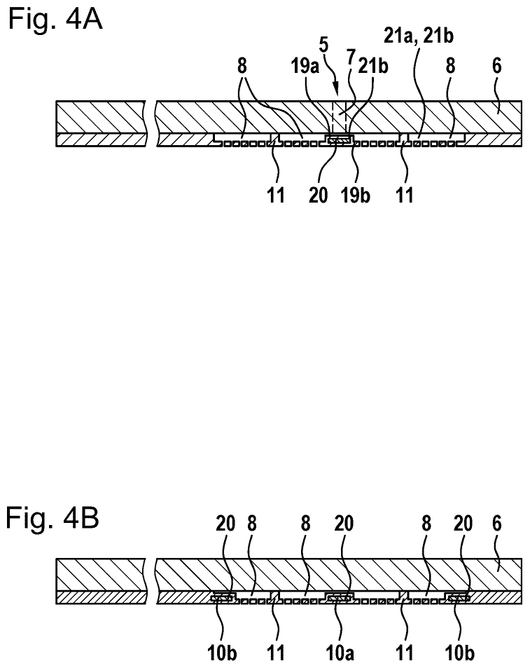

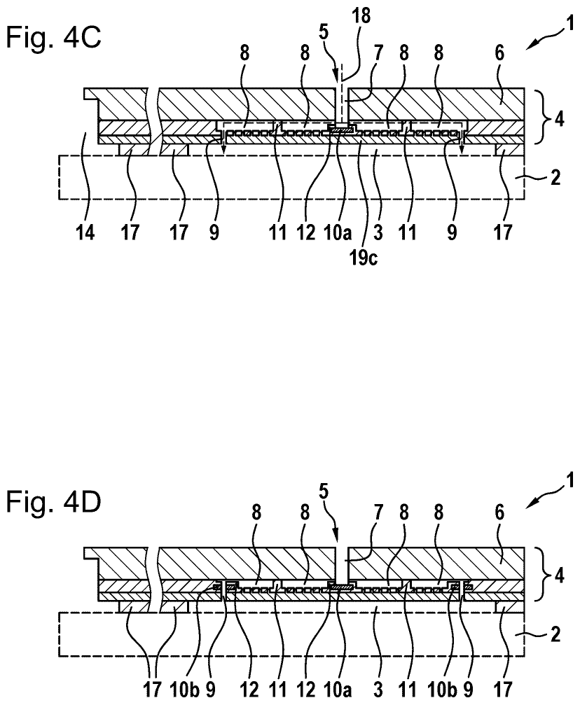

FIGS. 4A to 4D show a method for producing the microelectromechanical device 1 according to a third embodiment. Like the method described with reference to FIGS. 3A and 3B, the third embodiment is generally based on the deposition and later removal of sacrificial material layers 21a, 21b. A possible intermediate state of the cap structure 4 after the deposition and structuring of material layers and after the removal of the sacrificial material layers 21a, 21b is shown as an example in FIG. 4A. In a first method step, a first sacrificial material layer 21a made of silicon dioxide was deposited and structured such that a silicon dioxide-free region is created in the region of an inlet channel 7 Said silicon dioxide-free region is preferably configured centrally with respect to the inlet channel 7 and its outer perimeter extends peripherally at a defined distance from the outer perimeter of the inlet channel 7. After the structuring of the first sacrificial material layer 21a made of silicon dioxide, a second sacrificial material layer 21b made of silicon dioxide is deposited. The thickness of the second sacrificial material layer 21b can later be used to set a reduced height of the at least one lateral channel 8 in a region in which the first sacrificial material layer 21a was removed. After depositing the second sacrificial material layer 21b made of silicon dioxide, the first sacrificial material layer 21a and the second sacrificial material layer 21b can optionally be structured such that silicon dioxide-free regions are created that are used to produce later channel support structures 11.

In a subsequent second method step, a first silicon layer 19a was deposited and silicon dioxide-free regions were at least partially filled. A silicon dioxide layer 20 is then deposited In a third step, and the created surface is planarized using a CMP step such that the silicon dioxide layer 20 is removed from the surface of the first silicon layer 19a outside a silicon dioxide-free region in the first sacrificial material layer 21a and remains on the first silicon layer 19a only within a silicon dioxide-free region in the first sacrificial material layer 21a, which results in a flat surface. The silicon dioxide layer 20 remaining on the first silicon layer 19a in a silicon dioxide-free region of the first sacrificial material layer 21a can later be used as a first etch stop structure 10a and/or as a second etch stop structure 10b.

In a fourth method step, a second silicon layer 19b can be deposited and together with the first silicon layer 19a structured such that at least one etching access to the first sacrificial material layer 21a and the second sacrificial material layer 21b is created. Depositing a second silicon layer 19b causes the material of the silicon dioxide layer 21b remaining on the first silicon layer 19a in a silicon dioxide-free region of the first sacrificial material layer 21a to be completely enclosed with silicon and thus protected from etching attack when the first sacrificial material layer 21a and the second sacrificial material layer 21b made of silicon dioxide are removed.

In a fifth method step, the at least one etching access through the first silicon layer 19a and the second silicon layer 19b is closed after removal of the first sacrificial material layer 21a and the second sacrificial material layer 21b by depositing a third silicon layer 19c, so that at least one lateral channel 8 is created and the bonding structure 17 can subsequently be created.

Structuring the first silicon layer 19a, the second silicon layer 19b and the third silicon layer 19c together then enables the creation of at least one outlet channel 9 that opens into at least one lateral channel 8. In an alternative embodiment, the structuring of the first silicon layer 19a and the second silicon layer 19b and the deposition of the third silicon layer 19c can be omitted and the first and the second sacrificial material layer 21a, 21b can be removed in the at least one lateral channel 8 after the creation of the at least one outlet channel 9. It is optionally also possible to create a bond pad region recess 14 in the region of bond pad structures 22.

Analogous to FIG. 4A, FIG. 4B shows a variant in which second etch stop structures 10b can additionally be created in the region of the later at least one outlet channel 9 as in the above-described production process.

FIG. 4C shows the device 1 after the functional unit 2 has been connected to the cap structure 4 and the at least one inlet channel 7 has been created in the cap structure 4. The method steps carried out for this purpose can, for instance, be carried out in the same way as the fourth to eighth method steps of the method described in connection with FIGS. 2D to 2F. It can also be seen that removing the first sacrificial material layer 21a and the second sacrificial material layer 21b in the at least one lateral channel 8 not only creates channel support structures 11 but also channel block structures 12 in the region of the first etch stop structure 10a. These channel block structures cause narrowing of the lateral channels 8 in some sections, so that, for example, liquids or solid particles above a defined particle size are prevented from entering the cavity 3 by the channel block structures 12.

FIG. 4D shows the state of the device 1 analogous to FIG. 4C with respect to the variant shown in FIG. 4B, in which a respective additional etch stop structure 10b has been created in the region of two outlet channels 9, for example. As can be seen in FIG. 4D, the second etch stop structures 10b can be combined with a channel block structure 12 here as well.

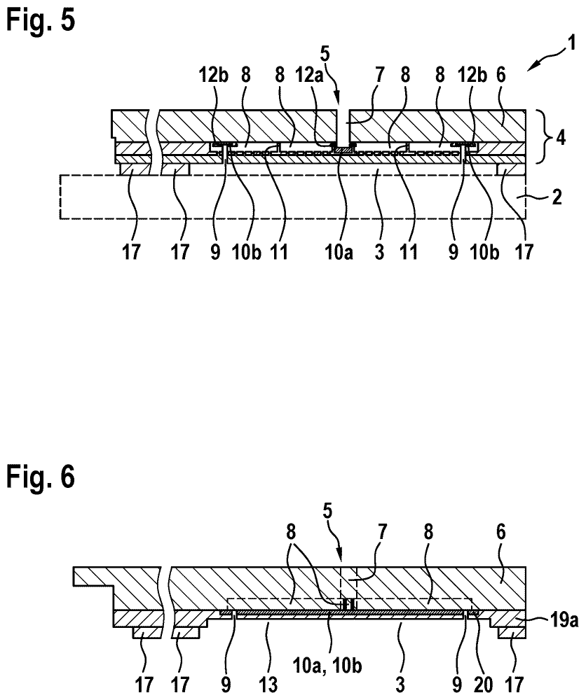

FIG. 5 shows a variant of the microelectromechanical device 1 and an associated production method according to a fifth embodiment. The fifth embodiment is based substantially on the fourth embodiment, but, due to a modified sequence of silicon and sacrificial material layers and their structuring and a suitable layout design, comprises a different arrangement of etch stop structures 10a, 10b and channel block structures 12. One difference from the fourth embodiment is that the first etch stop structure 10a and a first channel block structure 12a are spaced apart from the cap substrate 6 and the second etch stop structure 10b and a second channel block structure 12b are disposed directly on the cap substrate 6, so that the position of possible channel block structures 12 in the region of outlet channels 6 within the layer structure is different as well.

FIG. 6 uses a selected intermediate state of the produced device 1 to illustrate a sixth embodiment. The sixth embodiment is based substantially on the method described with reference to FIGS. 2A to 2G, wherein the intermediate state in FIG. 6 is comparable to the intermediate state shown in FIG. 2F. In the shown embodiment example, the created channels 8 are closed with a continuous silicon dioxide layer 20 as a continuous etch stop layer. The continuous silicon dioxide layer 20 thus serves to produce a common etch stop structure 10a, 10b for the at least one inlet channel 7, the at least one outlet channel 9 and also for other regions of the cap structure 4, so that further processing of the cap structure is facilitated and process reliability can be ensured. This also makes it possible to achieve a very flat cap structure 4 with few material layers, for example only a first silicon layer 19a in addition to the silicon dioxide layer 20.

The above-described methods and devices can be used to enable simple and reliable production as well as reliable and long-lasting operation of microelectromechanical devices.

1-13. (canceled)

14. A method for producing a microelectromechanical device which includes a functional unit, a cavity, and a cap structure that covers the cavity and has at least one cavity access, the method comprising:
producing the cap structure by sequentially depositing layers of material onto a cap substrate;
connecting the functional unit to the cap structure; and
creating in the cap structure at least one inlet channel in the at least one cavity access by etching;
wherein, during the production of the cap structure, at least one inlet channel, at least one outlet channel which opens into the cavity, and at least one lateral channel which extends parallel to a surface of the cap substrate and opens into the at least one inlet channel and into the at least one outlet channel are created in the cap structure; and
during the production of the cap structure, a first etch stop structure is created in the cap structure to limit a depth of the inlet channel.

15. The method according to claim 14, wherein, during the production of the cap structure, a second etch stop structure is created in the cap structure in a region of the at least one outlet channel.

16. The method according to claim 15, wherein the first etch stop structure and the second etch stop structure are created as a continuous etch stop layer.

17. The method according to claim 15, wherein the first and/or the second etch stop structure is created with a silicon dioxide layer.

18. The method according to claim 14, wherein at least one channel support structure and/or at least one channel block structure are created in the at least one lateral channel.

19. The method according to claim 14, wherein the at least one lateral channel is created in the cap substrate of the cap structure.

20. The method according to claim 14, wherein the at least one lateral channel is created by depositing, structuring, and at least partially removing at least one sacrificial material layer.

21. The method according to claim 20, wherein, immediately after structuring a first sacrificial material layer, at least in a region in which the first sacrificial material layer has been removed, a second sacrificial material layer, a first silicon layer, an etch stop layer, and a second silicon layer are deposited one after the after such that the etch stop layer is substantially completely surrounded by the first silicon layer and/or the second silicon layer.

22. The method according to claim 14, wherein, during the production of the cap structure, a cavity recess and/or a bond pad region recess and/or a through-opening are created in the cap structure in a region of bond pad structures.

23. The method according to claim 14, wherein, during the production of the cap structure, a plurality of lateral channels which extend parallel to a surface of the cap substrate are created in the cap structure.

24. The method according to claim 23, wherein at least two lateral channels are connected to one another by at least one connecting channel and/or open into one another.

25. The method according to claim 14, wherein at least one first etch stop structure and/or at least one first channel block structure is created at a distance from the cap substrate and wherein at least one second etch stop structure and/or at least one second channel block structure is created directly on the cap substrate.

26. A microelectromechanical device, comprising:
a functional unit;
a cavity; and
a cap structure that covers the cavity and has at least one cavity access;
wherein the cavity access includes at least one inlet channel, at least one outlet channel which opens into the cavity, and at least one lateral channel which extends parallel to a surface of the cap substrate and opens into the at least one inlet channel and into the at least one outlet channel, and
wherein the at least one inlet channel in the cap structure is limited in terms of its depth by a first etch stop structure.
